(19) United States
(12) Patent Application Publication
(10) Pub. No.: US 2009/0166890 A1
(43) Pub. Date: Jul. 2, 2009

(54) Flip-chip package

(76) Inventors: Gregory M. Chrysler, Sun Lakes, AZ (US); Ashish Gupta, Chandler, AZ (US)

Correspondence Address: ZEA , BARLOCCI & MARKVARDSEN, C/O INTELLEVATE , LLC, P.O BOX 52052, MINNEAPOLIS, MN, 55402, US

(21) Appl. No.: 12/006,286

(22) Filed: Dec. 31, 2007

(51) Int. Cl. H01L 23/48; H01L 21/02

(52) U.S. Cl. 257/778; 438/108; 257/E23.172; 257/E21.002

(57) ABSTRACT

A flip-chip package is described. The package has an integrated circuit (IC) die positioned within an epoxy layer on the top surface of a package substrate. Cooling of the IC die is facilitated by a heat spreader having two contact surfaces separated by a pedestal, the first contact surface for attachment to the epoxy layer the second contact surface for thermal attachment to the exposed backside surface of the IC die, the pedestal thickness is selected so as to create a gap between the first contact surface and the epoxy layer.

### BACKGROUND

Flip-chip package assemblies generally include an integrated circuit (IC) die that is mechanically and electrically connected to a supporting substrate via metallic bumps on the bottom surface of the die. The supporting substrate in conventional flip-chip packages is a multi-layered circuit having a relatively stiff core layer and a plurality of conductive or semiconductor layers having traces that are interconnect by vias between the layers. Heat management of the IC die is typically accomplished by the use of a heat spreader that is thermally coupled to the backside of the die.

Continued advancements in integrated circuit technology have resulted in the need for flip-chip package assemblies having higher electrical performance and routing density. One approach for enhancing package performance and routing density is the use of thinner core layers or the complete elimination of the core layer from the package substrate. However, thinning or omitting the core layer lowers the mechanical strength of the package and can result in unacceptable substrate warpage.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIGS. 1A and 1B represent an integrated circuit package in one embodiment of the present invention.

FIGS. 2A and 2B represent an integrated circuit package in yet another embodiment of the present invention.

FIGS. 3A and 3B represent integrated circuit packages in other embodiments of the present invention.

FIG. 4 is a heat spreader in one embodiment of the present invention.

FIG. 5 is a flowchart of a process for fabricating an integrated circuit package in one embodiment of the present invention.

### DETAILED DESCRIPTION

In the following description, numerous specific details are set forth in order to provide a thorough understanding of the present invention. It will be understood, however, to one skilled in the art, that the present invention may be practiced without some or all of these specific details. In other instances, well known process operations have not been described in detail in order not to unnecessarily obscure the present invention.

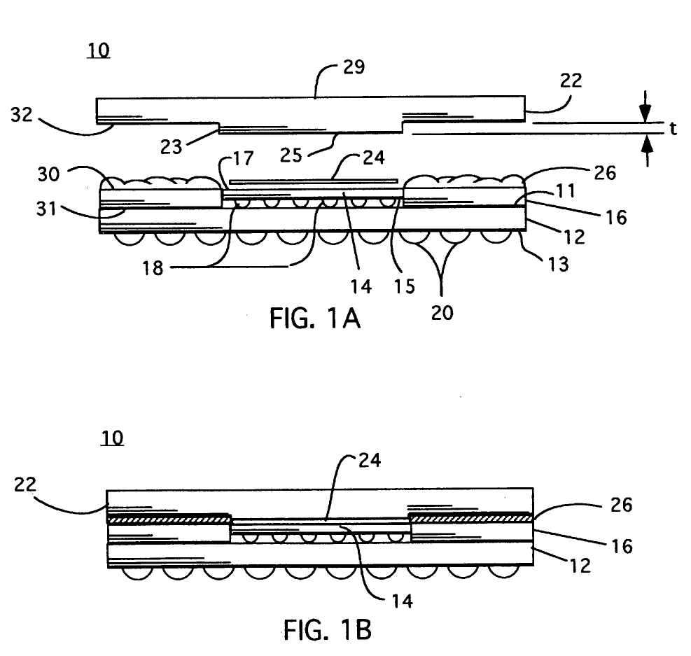

FIGS. 1A and 1B show a flip-chip integrated circuit (IC) package 10 in accordance with one embodiment of the present invention. Package 10 comprises a multi-layered circuit substrate 12 that is generally used to electrically connect an integrated circuit (IC) die 14 supported by the substrate to a printed circuit board (not shown), such as, for example, a motherboard. A plurality of metallic bumps 18 electrically and mechanically connects pads (not shown) located on the bottom surface 15 of IC die 14 to pads (not shown) on the top surface 11 of substrate 12. An adhesive underfill material (not shown) may be used to occupy the region between the bumps 18 to further bond the IC die 14 to substrate 12.

Multi-layered circuit substrate 12 is formed by well known processes used to create integrated circuits and printed circuit boards. In one embodiment, substrate 12 includes a core layer and a plurality interconnected conductive or semiconductor layers having traces (not shown) that electrically connect the IC die 14 to electrical connectors 20 located on the bottom surface 13 of the substrate. The core layer generally comprises a metal, such as copper, or a dielectric material, such as a glass fiber reinforced epoxy having thicknesses in the range of about 15.0 mils to about 28.0 mils. In alternative embodiments substrate 12 includes a core layer of reduced thickness or is devoid of a core layer altogether to enhance electrical performance and routing density of the package. Electrical connectors 20 may comprise metallic bumps (as shown in FIGS. 1A and 1B), pins, lands, or other suitable IC package to printed circuit board connection methods. It is important to note that the present invention is not limited by the method in which IC die 14 is connected to substrate 12, nor by the method in which substrate 12 is connected to external devices (e.g., printed circuit boards). For example, optical connection methods may be used.

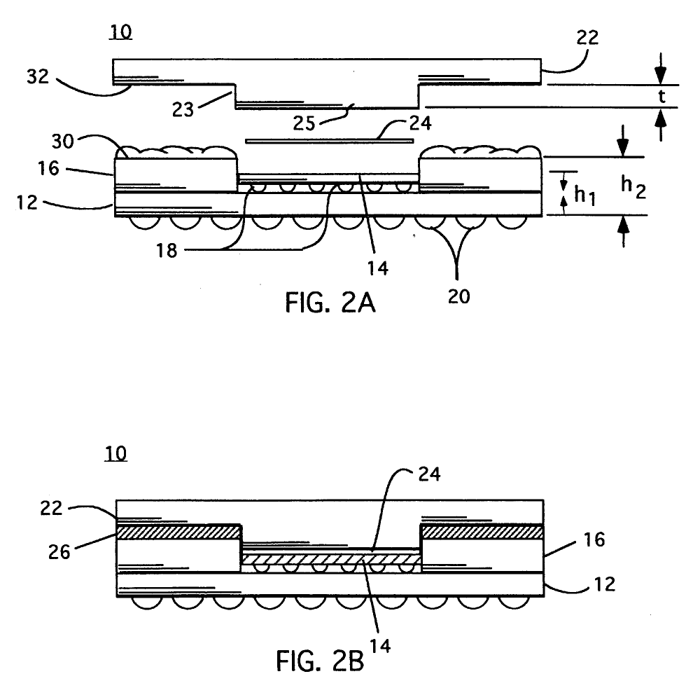

An epoxy layer 16 having a top surface 30 and a bottom surface 31 is attached to the top surface 11 of substrate 12, the top surface 30 being generally planar with the top surface 17 of IC die 14. In an alternative embodiment as shown in FIGS. 2A and 2B, the top surface 30 of epoxy layer 16 has a height, h1, greater than the height, h2, of the top surface 17 of IC die 14. Epoxy layer 16 may cover a portion of the top surface 11 or may preferably cover the entire surface as shown in FIG. 1B. Epoxy layer 16 is typically attached to substrate 12 after the IC die 14 has been attached to substrate 12 and is preferably molded onto the top surface 11. Epoxy layer 16 is made of a formable molding compound that has a coefficient of thermal expansion near that of substrate 12. The molding compound may include, for example, an epoxy containing a phenolic hardener, spherical silica filler in addition to adhesion promoters, flame retardants, etc.. An adhesion promotion material may be applied to the top surface 11 of substrate 12 prior to the molding process to promote adhesion between the epoxy layer 16 and substrate 12.

A heat spreader 22 is attached to the top surface 30 of epoxy layer 16 and is thermally coupled with the top surface 17 of IC die 14. Heat spreader 22 is formed from a high thermal conductive material (e.g., copper, aluminium, highly conductive composite materials, etc.) and provides a path for the removal of heat from the IC die 14. Heat spreader 22 has a top surface 29, a first contact surface 32 opposite top surface 29, and a pedestal 23 extending from the first contact surface 32. The pedestal has a thickness, t, and comprises a second contact surface 25 that is substantially parallel with the first contact surface 32 and the top surface 17 of IC die 14. Coupling of the heat spreader 22 to the IC die 14 is made by use of a thermal interface material (TIM) 24 disposed between the top surface 17 of IC die 14 and the second contact surface 25 of the heat spreader. Examples of TIM include solders, polymers, polymer gels and polymer/solder hybrids. Further attachment of the heat spreader 22 to package 10 is made by use of an adhesive 26 positioned between the gap located between the first contact surface 32 of the heat spreader to the top surface 30 of substrate 12. Adhesive 26 may include silicone or other proprietary adhesive material. In use with solder TIM thin gold layer (not shown) is typically formed, or otherwise deposited, onto the top surface 17 of IC die 14 and the second contact surface 25 of heat spreader 22 to enhance wetting and bonding of the solder TIM to the respective surfaces. In accordance with one embodiment of the present invention attachment of heat spreader 22 to IC die 14 is accomplished by depositing a flux to the top surface 17 of IC die 14, placing a solder TIM preform (preferably having a thickness of about 10.0 to about 15.0 mils) over the applied flux and fluxing the top surface of the TIM preform. Before, concurrently, or after the preceding steps an adhesive is applied to either the top surface 30 of epoxy layer 16 or the first contact surface 32 of heat spreader 22. The heat spreader 22 is then positioned atop package 10 so that the second contact surface 25 is adjacent to the top surface 17 of IC die 14 and the first contact surface 32 is adjacent the top surface 30 of epoxy layer 16. The assembly is then heated to reflow the TIM 24 and to cure the adhesive 26. In an alternative embodiment, a polymer TIM (preferably having a thickness of about 1.0 to about 5.0 mils) is dispensed onto the fluxed top surface 17 of IC die 14 in lieu of using a solder TIM preform.

As described above, heat spreader 22 includes a pedestal 23 having a thickness, t. An advantage of the heat spreader of the present invention is that the pedestal thickness, t, can be selected to ensure a consistent thermal couple between the second contact surface 25 and the top surface 17 of IC die 14 while accommodating variations in package component heights (e.g., IC die 14, epoxy layer 16) and package component thicknesses (e.g., TIM 24 and adhesive 26). For example, as shown in FIGS. 2A and 2B, the thickness, t, of pedestal 23 is greater than that of FIGS. 1A and 1B to accommodate for the height difference between the top surface 17 of IC die 14 and the top surface 30 of epoxy layer 16. Moreover, the variability of the thickness, t, of pedestal 23 enables a greater selection of TIM and adhesive materials and thicknesses to be used within package 10.

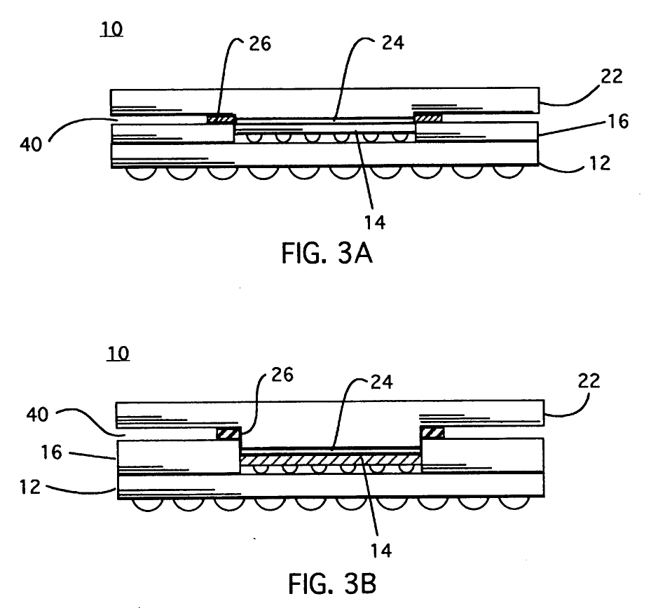

As discussed above, multi-layered circuit substrate 12 may comprise a core layer of typical thickness, a core layer of reduced thickness or can alternatively be devoid of a core layer altogether. Moreover, the thicknesses, materials and general construction of the substrate 12 and epoxy layer 16 may also vary. Each of these variations, including others, will affect the flexibility of the package 10 and, consequently, the flexibility of substrate 12 that contains electronic components that can be damaged by excess warpage of the substrate. Another feature of the present invention is its ability to provide variable flexibility to package 10 by the strategic placement of the adhesive 26 between the first contact surface 32 of heat spreader 22 and the top surface 30 of epoxy layer 16. In the embodiments of FIGS. 1 and 2, adhesive 26 occupies the entire space between the first contact surface 32 of heat spreader 22 and the top surface 30 of epoxy layer 16 to provide maximum stiffness to package 10. This arrangement may be most useful in packages having coreless or thin core substrates. In alternative embodiments, as shown in FIGS. 3A and 3B, adhesive 26 may occupy only a portion of the space between the first contact surface 32 of heat spreader 22 and the top surface 30 of epoxy layer 16 so that a gap 40 exists between the two surfaces. (Note that the thickness, t, of pedestal 23 of heat spreader 22 ensures the existence of gap 40.) For example, in the embodiments of FIGS. 3A and 3B, adhesive 26 occupies only the portion of gap 40 adjacent the pedestal 23. This arrangement may be most useful in packages having conventional core layers or those with relatively thick and/or stiff epoxy layers.

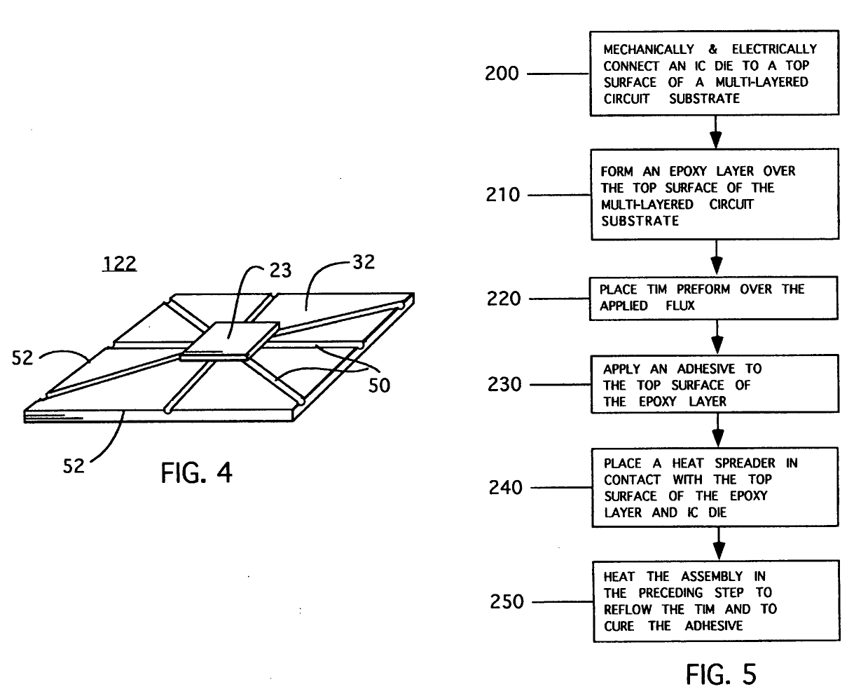

FIG. 4 illustrates a heat spreader 122 in another embodiment of the present invention. Heat spreader 122 includes a plurality of grooves 50 formed within the first contact surface 32 that extend radially from regions near pedestal 23 to the outer edges 52 of heat spreader 122. Epoxy adhesives and fluxes used in the assembly of the IC package 10 tend to outgas. The grooves 50 are provided for placement of the adhesive 26 when attaching the heat spreader 122 to the epoxy layer 16 and provide a route for gases to vent during the curing process or post manufacturing. Because the pedestal 23 always ensures that a gap exists between the first contact surface 32 and top surface 30 of epoxy layer 16, it is not necessary that grooves 50 extend to the outer edges 52 of the heat spreader 122. As a result, variable flexibility may be achieved with heat spreader 122 much in the same manner as described above with respect to the embodiments of FIGS. 1, 2 and 3.

FIG. 5 is a flow chart of a process for fabricating an integrated circuit package in accordance with one embodiment of the present invention. Beginning at block 200, an IC circuit die is mechanically and electrically connected to a top surface of a multi-layered circuit substrate. An epoxy layer is then formed over the top surface of the substrate as provided in block 210. A TIM material is then positioned over the exposed top surface of the IC die as provided in block 220. A flux is typically applied to the top surface of the die prior to placement of the TIM and is typically applied again to the exposed TIM surface after its placement. Before, concurrently, or after the preceding step an adhesive is applied to either the top surface of the epoxy layer or to the first contact surface of the heat spreader as provided in block 230. In block 240, the heat spreader is positioned atop the package so that the second contact surface is adjacent to the top surface of the IC die and the first contact surface is adjacent the top surface of epoxy layer. The package assembly is then heated to reflow the TIM and to cure the adhesive.

Other embodiments of the invention will be appreciated by those skilled in the art from consideration of the specification and practice of the invention. Furthermore, certain terminology has been used for the purpose of descriptive clarity, and not ot limit the present invention. The embodiments and preferred features described above should be considered exemplary, with the invention being defined by the appended claims.

1. An integrated circuit (IC) package comprising,
a multi-layered circuit substrate comprising a top surface and an opposing bottom surface,
an IC die comprising a top surface having a first height, an opposing bottom surface, the bottom surface of the IC die electrically connected to the top surface of the substrate,
an epoxy layer having a second height disposed on at least a portion of the top surface of the substrate, the epoxy layer comprising a top surface and an opposing bottom surface,
a heat spreader bonded to the top surface of the epoxy layer and in thermal contact with the top surface of the IC die, the heat spreader comprising a top surface, a first contact surface opposite the top surface and a pedestal extending from the first contact surface, the pedestal having a thickness and comprising a second contact surface that is substantially parallel to the first contact surface and to the top surface of the IC die, the thickness sufficient to create a gap between the first contact surface and the top surface of the epoxy layer,
a thermal interface material (TIM) disposed between the second contact surface of the heat spreader and the top surface of the IC die; and
an adhesive disposed in at least a portion of the gap between the first contact surface of the heat spreader and the top surface of the epoxy layer to bond the heat spreader to the epoxy layer.

2. The IC package of claim 1 wherein the adhesive is disposed in only a portion of the gap adjacent the pedestal.

3. The IC package of claim 1 wherein the adhesive occupies the entire gap between the first contact surface of the heat spreader and the top surface of the molded epoxy layer.

4. The IC package of claim 1 wherein the first contact surface of the heat spreader comprises one or more radial grooves extending to the perimeter of the heat spreader, the adhesive disposed only in the one or more grooves.

5. The IC package of claim 1 wherein the first contact surface of the heat spreader comprises one or more radial grooves extending from a point at or near the pedestal to the perimeter of the heat spreader, the adhesive disposed only in the one or more grooves.

6. The IC package of claim 1 wherein the multi-layered circuit substrate is coreless.

7. The IC package of claim 1 wherein the second height is equal to the first height.

8. The IC package of claim 1 wherein the second height is greater than the first height.

9. The IC package of claim 1 wherein the epoxy layer is a molded epoxy layer.

10. (canceled)

11. (canceled)

12. (canceled)

13. (canceled)

14. (canceled)

15. (canceled)
